(19) United States
(12) Patent Application Publication
(10) Pub. No.: US 2007/0216971 A1
(43) Pub. Date: Sep. 20, 2007

(54) Color correction circuit, image display apparatus including the same, and color correction method

(75) Inventor: Fumio Koyama, Shiojiri-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/710,960

(22) Filed: Feb. 27, 2007

(30) Foreign Application Priority Data
Mar. 16, 2006 (JP) 2006-072533

(51) Int. Cl. G03F 3/08

(52) U.S. Cl. 358/518; 358/1.9

(57) ABSTRACT

A color correction circuit includes a 3D-LUT, an off data generation circuit, an image signal switchover circuit, and an interpolation operation circuit. The off data generation circuit substitutes respective lower (k−n) bits of input R, G, and B signals R2, G2, and B2 with a value ‘0’ and outputs processed R, G, and B signals after the substitution as off data Or, Og, and Ob. The off data generation circuit accordingly gives the output equivalent to the output of the 3D-LUT on the assumption that the storage of the 3D-LUT is rewritten to have identical input and output. The image signal switchover circuit alternatively selects and outputs standard data Sr, Sg, and Sb input from the 3D-LUT and the off data Or, Og, and Ob input from the off data generation circuit according to the setting of an externally given correction prohibit signal F. The color correction function of the color correction circuit is thus readily activated and inactivated, in response to the correction prohibit signal F. The arrangement of the invention effectively attains size reduction of the circuit scale and prevents the disturbance of image display due to deviation of the signal transfer timing, while enabling inactivation of the color correction function.

### CROSS REFERENCE TO RELATED APPLICATIONS

The present application claims the priority based on Japanese Patent Application No. 2006-72533 filed on Mar. 16, 2006, the disclosure of which is hereby incorporated by reference in its entirety.

### BACKGROUND OF THE INVENTION

1. Field of the Invention

The present invention relates to a technique of correcting the color of a color image displayed on an image display apparatus, such as a liquid crystal projector.

2. Description of the Related Art

Conventional liquid crystal projectors used as one type of image display apparatuses may have a color correction circuit utilizing a three-dimensional lookup table (hereafter referred to as ‘3D-LUT’) for accurate color reproduction of images according to input signals. This technique is disclosed in, for example, JP 2002-41016A, JP 2002-140060A, JP 2002-344761A, and JP 2003-271122 A and JP 58-16180B2. R, G, and B signals typically input into the color correction circuit are generally tone data of 8 or a greater number of bits and are expressed by at least 256 tone values. The 3D-LUT is accordingly required to store at least (256×256×256) correction values corresponding to all the combinations of the tone values of the R, G, and B signals. Namely the storage of the 3D-LUT occupies a significantly large memory capacity.

In the actual application, the required memory capacity for storage of the 3D-LUT is reduced by storing correction values corresponding not to all the combinations of the tone values of the input R, G, and B signals but to only selected combinations of the tone values extracted at adequate intervals. One concrete example stores correction values corresponding to combinations of the upper 3-bit or 4-bit tone values of the R, G, and B signals. The correction values read from the 3D-LUT are then subjected to an interpolation operation based on the remaining lower bits of the R, G, and B signals other than the upper 3 bits or 4 bits (see the above cited reference, JP 58-16180B2).

The image display apparatus including the color correction circuit may occasionally require inactivation of the function of the color correction circuit. One available technique uses the software configuration of rewriting the storage of the 3D-LUT to inactivate the function of the color correction circuit. Rewriting the storage, however, takes a relatively long time and does not allow instantaneous inactivation of the function of the color correction circuit. There is accordingly a noise on a resulting output image. Another available technique causes a hardware structure of inactivating the function of the color correction function to be mounted on the color correction circuit.

Mounting the hardware structure on the color correction circuit, however, undesirably expands the overall circuit scale. When the hardware structure provides a signal pathway bypassing the color correction circuit, another disadvantage is a deviation of the signal transfer timing in the state of the inactive color correction function from the signal transfer timing in the state of the active color correction function. This leads to a horizontal misalignment of the resulting displayed image.

### SUMMARY

There are accordingly needs for reducing the circuit scale and preventing the disturbance of image display due to deviation of the signal transfer timing, while enabling inactivation of the color correction function.

According to a first aspect of the present invention, there is provided a color correction circuit that receives three color signals representing a color image as input signals and performs signal processing of the input signals to correct the color of the color image displayed on an image display apparatus. The color correction circuit includes: a standard data acquisition module that divides each of the three input color signals into an upper bit portion and a lower bit portion and acquires standard data for correction corresponding to a combination of the respective upper bit portions of the three color signals; an interpolation operation module that performs an interpolation operation of the standard data based on the respective lower bit portions of the three color signals to generate color-corrected output signals; an off data generation module that divides each of the three input color signals into an upper bit portion and a lower bit portion, which have identical bit widths with the bit widths of the upper bit portion and the lower bit portion by the standard data acquisition module, substitutes the respective lower bit portions of the three color signals with a value ‘0’, and outputs three processed color signals after the substitution as off data; and an interpolation object switchover module that, in response to an externally given correction prohibit instruction for prohibiting color correction, switches over an interpolation object of the interpolation operation module from the standard data to the off data.

The standard data for correction is acquired corresponding to the combination of the respective upper bit portions of three input color signals representing a color image. The standard data is subjected to the interpolation operation based on the respective lower bits portions of the three color signals, and the processed standard data after the interpolation operation are output as the color-corrected output signals. The respective lower bit portions of the three color signals are substituted with the value ‘0’, and the three processed color signals after the substitution are output as the off data. In response to the externally given correction prohibit instruction, the interpolation object of the interpolation operation is switched over from the standard data to the off data.

The off data have the identical bit widths with the bit widths of the three color signals. The upper bit portions of the off data (having the same bit widths of the upper bit portions used for acquisition of the standard data) have the identical values with the values of the upper bit portions of the color signals. The lower bit portions of the off data (having the same bit widths of the lower bit portions used for acquisition of the standard data) are equal to 0. The off data are subjected to the interpolation operation based on the respective lower bit portions of the three color signals. The three processed color signals output from the interpolation operation module are thus equivalent to the color signals input into the color correction circuit. In this state, the color correction circuit inactivates the color correction function and directly outputs the three input color signals as its output signals.

The color correction circuit of the first aspect of the invention readily inactivates the color correction function in response to the correction prohibit instruction. The interpolation operation circuit requiring the longest time for signal transfer continues activation even in the state of the inactive color correction function. The continued activation of the interpolation operation circuit desirably prevents a deviation of the signal transfer timing in the state of the inactive color correction function from the signal transfer timing in the state of the active color correction function. This desirably prevents the disturbance of image display due to the deviated transfer timing. The off data generation module has the simple circuit structure and does not cause the overall size expansion of the color correction circuit. The color correction circuit thus effectively attains size reduction of the circuit scale and prevents the disturbance of image display due to deviation of the signal transfer timing, while enabling inactivation of the color correction function.

The three color signals may be, for example, a red color signal, a green color signal, and a blue color signal. In this case, the color correction circuit performs color correction of general R, G, and B signals as its input signals.

It is preferable that the standard data acquisition module has a three-dimensional lookup table that inputs the combination of the respective upper bit portions of the three color input signals as an address signal and outputs the standard data for correction corresponding to the combination of the respective upper bit portions of the three color images.

This application simply requires prior preparation and storage of the three-dimensional lookup table in a memory circuit, thus desirably simplifying the construction of the color correction circuit.

It is also preferable that the three-dimensional lookup table stores the standard data for correction at each of lattice points specified by division of a color space of the three colors into lattices. The three-dimensional lookup table divides each unit cube defined by preset lattice points in the color space into multiple tetrahedrons and outputs the standard data at respective apexes of each of the multiple tetrahedrons, which include one specific point corresponding to a combination of tone values of the upper bit portions. The interpolation operation module performs linear interpolation of the standard data for correction output from the three-dimensional lookup table to generate color-corrected data corresponding to tone values of the lower bit portions.

The interpolation operation module uses a simple computational expression to smoothly attain linear interpolation. This readily and stably makes the output signal of the color correction circuit equivalent to the input signal of the color correction circuit.

It is also preferable that the interpolation object switchover module includes a signal switchover circuit that receives both an output signal of the standard data acquisition module and an output signal of the off data generation module, and outputs the output signal of the off data generation module to the interpolation operation module in response to external input of the correction prohibit instruction while outputting the output signal of the standard data generation module to the interpolation operation module in response to no external input of the correction prohibit instruction.

The signal switchover circuit readily activates and inactivates the color correction function of the color correction circuit.

The technique of the first aspect of the invention is not restricted to the various aspects of the color correction circuits described above but is also actualized by an image display apparatus including the color correction circuit.

According to a second aspect of the present invention, there is provided a color correction method of receiving three color signals that represent a color image as input signals and performing signal processing of the input signals to correct the color of the color image displayed on an image display apparatus.

The color correction method divides each of the three input color signals into an upper bit portion and a lower bit portion and acquires standard data for correction corresponding to a combination of the respective upper bit portions of the three color signals. The color correction method performs an interpolation operation of the standard data based on the respective lower bit portions of the three color signals to generate color-corrected output signals. The color correction method divides each of the three input color signals into an upper bit portion and a lower bit portion, which have identical bit widths with the bit widths of the divided upper bit portion and lower bit portion, substitutes the respective lower bit portions of the three color signals with a value ‘0’, and outputs three processed color signals after the substitution as off data. In response to an externally given correction prohibit instruction for prohibiting color correction, the color correction method switches over an interpolation object of the interpolation operation from the standard data to the off data.

Like the color correction circuit of the first aspect of the invention described above, the corresponding color correction method of the second aspect of the invention attains size reduction of the circuit scale and prevents the disturbance of image display due to deviation of the signal transfer timing, while enabling inactivation of the color correction function.

### BRIEF DESCRIPTION OF THE DRAWINGS

FIG. 1 is a block diagram schematically illustrating the configuration of a liquid crystal projector including a color correction circuit in one embodiment of the invention;

FIG. 2 is a block diagram showing the structure of the color correction circuit of the embodiment;

FIG. 3 shows the structure of off data Or generated by an off data generation circuit included in the color correction circuit;

FIG. 4 shows one hardware configuration for inactivating the color correction function of the color correction circuit as a first reference example; and

FIG. 5 shows another hardware configuration for inactivating the color correction function of the color correction circuit as a second reference example.

### DESCRIPTION OF THE PREFERRED EMBODIMENTS

One mode of carrying out the invention is described below in the following sequence as a preferred embodiment with reference to the accompanied drawings:

A. General Configuration of Liquid Crystal Projector

B. Color Correction Circuit

C. Functions and Effects

D. Modifications

A. General Configuration of Liquid Crystal Projector

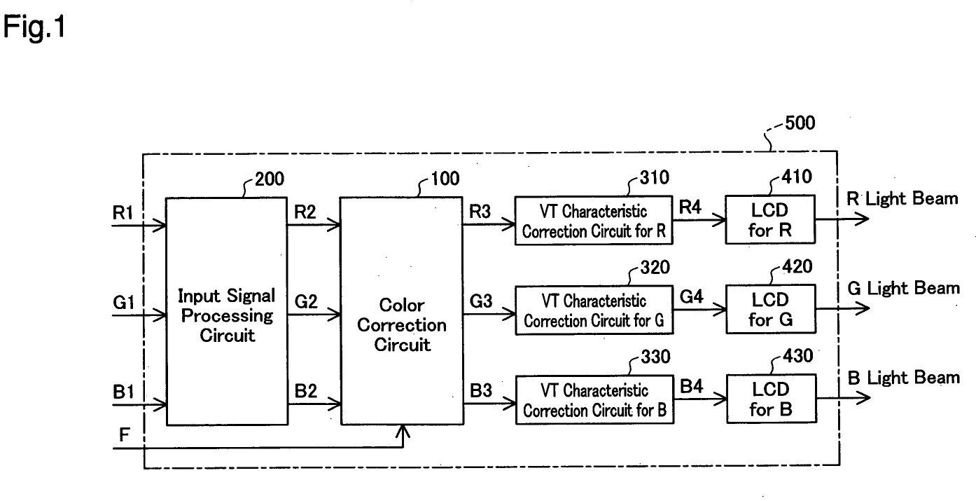

FIG. 1 is a block diagram schematically illustrating the configuration of a liquid crystal projector 500 including a color correction circuit 100 in one embodiment of the invention. The liquid crystal projector 500 shown in FIG. 1 is a three-panel type and has three liquid crystal panels (hereafter may be referred to as LCDs) 410 through 430 for three colors R (red), G (green), and B (blue) as display devices. The liquid crystal projector 500 also includes an input signal processing circuit 200 and VT characteristic correction circuits 310 through 330 for the three colors R, G, and B, in addition to the color correction circuit 100 of the invention.

The input signal processing circuit 200 receives externally input R, G, and B signals R1, G1, and B1 as image signal and performs a required series of processing on the input R, G, and B signals R1, G1, and B1. When the input image signal is an analog signal, the input signal processing circuit 200 performs analog-to-digital conversion. The input signal processing circuit 200 may perform frame rate conversion or a resizing operation according to the format of these input signals or may superpose a menu window for menu display. When the input image signal is a composite signal, the input signal processing circuit 200 demodulates the input composite signal and separates the demodulated composite signal into R, G, and B signals and synchronizing signals.

The color correction circuit 100 performs correction of digital R, G, and B signals R2, G2, and B2 output from the input signal processing circuit 200 to correct the mixing color of transmitted light beams (color light beams) emitted from the respective liquid crystal panels 410 through 430. The R, G, and B signals R2, G2, and B2 have a number of bits k satisfying k≧8. In the description hereof, it is assumed that the R, G, and B signals R2, G2, and B2 have the number of bits k=8. The color correction circuit 100 receives an externally input correction prohibit signal F and inactivates the functions of color correction in response to setting of the correction prohibit signal F equal to ‘1’. The correction prohibit signal F is sent from a sender of the image signal, for example, a computer, to require a change of the color modulation characteristic. The correction prohibit signal F may alternatively be generated in the liquid crystal projector 500. In one applicable structure, the liquid crystal projector 500 may have a switch for changing the color modulation characteristic. The liquid crystal projector 500 generates the correction prohibit signal F, in response to the operator's manipulation of the switch. The ‘correction prohibit instruction’ of the invention may be generated inside or outside the liquid crystal projector 500, as long as the color correction circuit 100 externally receives the correction prohibit instruction.

The VT characteristic correction circuits 310 through 330 for R, G, and B respectively perform γ correction of color-corrected R, G, and B signals R3, G3, and B3 output from the color correction circuit 100 by taking into account the VT characteristics (voltage-transmittance characteristics) of the liquid crystal panels 410 through 430 for R, G, and B. The VT characteristic correction circuits 310 through 330 for R, G, and B generally have one-dimensional lookup tables (1D-LUT).

The liquid crystal panels 410 through 430 for the three colors R, G, and B respectively receive R, G, and B signals R4, G4, and B4 output from the VT characteristic correction circuits 310 through 330 and emit transmitted R, G, and B light beams (color light beams) according to the received R, G, and B signals R4, G4, and B4. The illumination light emitted from a lighting optical system (not shown) is separated into R, G, and B color light beams, which respectively enter the liquid crystal panels 410 through 430 of the corresponding colors. The R, G, and B signals R4, G4, and B4 output from the CT characteristic correction circuits 310 through 330 also enter the liquid crystal panels 410 through 430 of the corresponding colors. The corresponding liquid crystal panel is activated in response to each input color signal to enable transmission of the corresponding input color light beam.

The transmitted R, G, and B light beams (color light beams) emitted from the R, G, and B liquid crystal panels 410 through 430 are mixed and are projected on a screen (not shown) by means of a projection optical system (not shown) to form a displayed color image on the screen according to the R, G, and B signals.

B. Color Correction Circuit

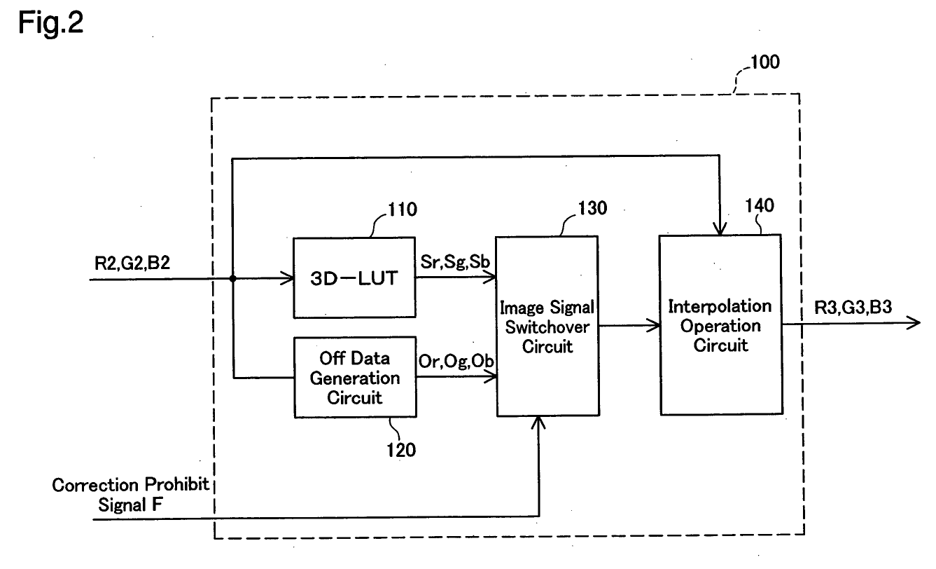

FIG. 2 is a block diagram showing the structure of the color correction circuit 100. The color correction circuit 100 includes a 3D-LUT 110, an off data generation circuit 120, an image signal switchover circuit 130, and an interpolation operation circuit 140 as shown in FIG. 2. The digital R, G, and B signals R2, G2, and B2 output from the input signal processing circuit 200 enter the 3D-LUT 110 and the off data generation circuit 120.

The 3D-LUT 110 is a memory circuit for storage of k-bit R signal standard data Sr, k-bit G signal standard data Sg, and k-bit B signal standard data Sb as correction values corresponding to combinations of respective upper ‘n’ bits of the R, G, and B signals R2, G2, and B2 (where ‘n’ denotes an integer of not less than 1 and not greater than (k−1)). The 3D-LUT 110 extracts the respective upper ‘n’ bits from the input R, G, and B signals R2, G2, and B2 and outputs the (3×k)-bit standard data Sr, Sg, and Sb according to the combinations of the three extracted upper ‘n’ bits. This memory circuit using a RAM with an (n+n+n)-bit address sequentially allocates the (n+n+n)-bit address in a descending bit order to the upper ‘n’ bits of the R signal R2, the upper ‘n’ bits of the G signal G2, and the upper ‘n’ bits of the B signal B2, while allocating the (3×k)-bit output to the outputs of the R signal standard data Sr, the G signal standard data Sg, and the B signal standard data by every k bits from the upper-most bit.

The 3D-LUT 110 gives correction values at respective lattice points specified by dividing a color space of the three colors R, G, and B into lattices. The correction values corresponding to only selected combinations of tone values of the R, G, and B signals extracted at adequate intervals are then output in the form of the R signal standard data Sr, the G signal standard data Sg, and the B signal standard data Sb.

The respective upper ‘n’ bits of the R, G, and B signals R2, G2, and B2 are equivalent to the ‘upper bit portion’ of the invention. For example, when ‘n’=3, the 3D-LUT 110 uses a RAM having ‘n+n+n’=9-bit address. When the R, G, and B signals R2, G2, and B2 are digital signals R2=‘00100010’, G2=‘00000000’, and B2=‘00000000’, the respective upper ‘n’ bits are ‘001’, ‘000’, and ‘000’. The 3D-LUT 110 accordingly outputs (3×k)-bit correction values stored at the address of ‘00100000’ in the memory circuit, for example, R signal standard data Sr=‘00101000’, G signal standard data Sg=‘00000000’, and B signal standard data Sb=‘00000000’.

The output signal of the 3D-LUT 110 is sent to the image signal switchover circuit 130, and may further be sent to the interpolation operation circuit 140 in the case of selection by the image signal switchover circuit 130.

The interpolation operation circuit 140 receives the R, G, and B signals R2, G2, and B2 output from the input signal processing circuit 200. The interpolation operation circuit 140 performs an interpolation operation of the respective color signal standard data Sr, Sg, and Sb sent from the 3D-LUT 110 via the image signal switchover circuit 130. The interpolation operation is based on the respective lower (k−n) bits of the input R, G, and B signals R2, G2, and B2 other than the upper ‘n’ bits. After the interpolation operation, the processed R, G, and B signals R2, G2, B2 are output from the interpolation operation circuit 140 as the color-corrected signals R, G, and B signals R3, G3, and B3.

An interpolation operation algorithm adopted in the interpolation operation circuit 140 may be, for example, the algorithm disclosed in the cited reference, JP 58-16180B2. The 3D-LUT 110 divides each unit cube defined by preset lattice points in the color space into multiple tetrahedrons, specifies the respective apexes of each tetrahedron including one specific point corresponding to the combination of the respective upper ‘n’ bits of the R, G, and B signals R2, G2, and B2, and outputs standard data representing the specified apexes. The interpolation operation circuit 140 performs linear interpolation of the standard data output from the 3D-LUT 110 to determine color-corrected data corresponding to the tone values of the respective lower (k−n) bits. The concrete procedure of the interpolation operation identifies a tetrahedron including a target point of interpolation defined by the lower (k−n) bits and performs linear interpolation of the standard data located at the respective apexes of the identified tetrahedron to determine color-corrected data corresponding to the lower (k−n) bits.

The interpolation operation algorithm adopted in the interpolation operation circuit 140 is not restricted to the above example but may be replaced with any other suitable interpolation operation algorithm for linear interpolation. The respective lower (k−n) bits of the R, G, and B signals R2, G2, and B2 are equivalent to the ‘lower bit portion’ of the invention.

The off data generation circuit 120 is arranged in parallel to the 3D-LUT 110 and receives the R, G, and B signals R2, G2, and B2 output from the input signal processing circuit 200. The off data generation circuit 120 substitutes 0 into the respective (k−n) bits of the input R, G, and B signals R2, G2, and B2 and outputs the three substituted R, G, and B signals as off data Or, Og, and Ob. The position of the lower (k−n) bits substituted by the off data generation circuit 120 is identical with the position of the lower (k−n) bits used in the interpolation operation circuit 140.

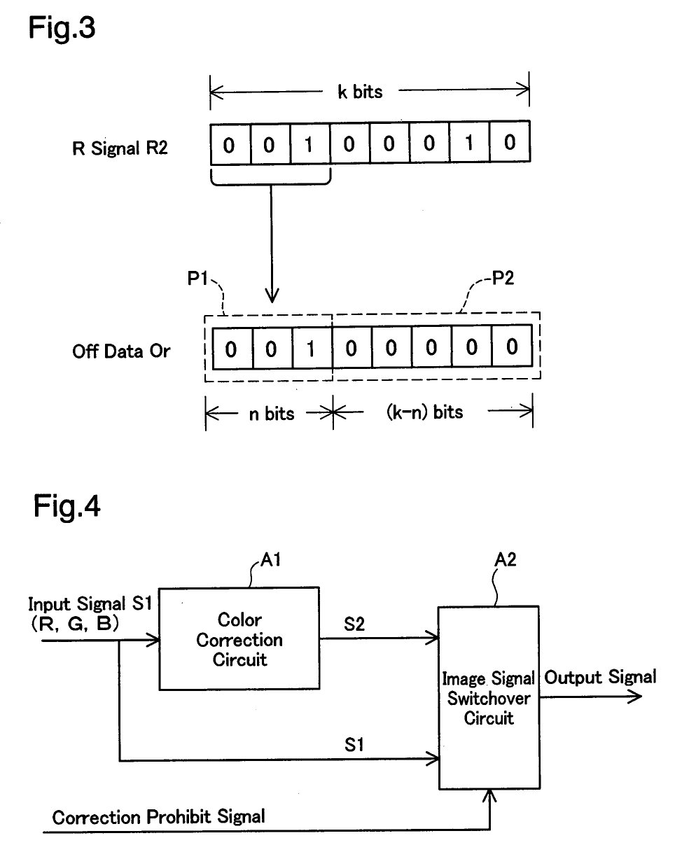

FIG. 3 shows the structure of the off data Or generated corresponding to the R signal. The off data Or has the same data length of ‘k’ bits as that of the R, G, and B signals R2, G2, and B2. An upper ‘n’-bit portion p1 of the off data Or has the same value as that of the upper ‘n’ bits of the R signal R2, whereas a lower (k−n)-bit portion p2 has the value of ‘0’. In the similar manner, the off data Og and Ob corresponding to the G signal G2 and the B signal B2 respectively have the data length of ‘k’ bits, where their upper ‘n’-bit portions have the same values as those of the upper ‘n’ bits of the G signal G2 and the upper ‘n’ bits of the B signal B2 and their lower (k−n)-bit portions have the values of ‘0’.

Namely the off data generation circuit 120 gives the output equivalent to the output of the 3D-LUT 110 on the assumption that the storage of the 3D-LUT 110 is rewritten to have identical input and output. The output signal of the off data generation circuit 120 is sent to the image signal switchover circuit 130, and may further be sent to the interpolation operation circuit 140 in the case of selection by the image signal switchover circuit 130.

The image signal switchover circuit 130 alternatively selects and outputs the standard data Sr, Sg, and Sb input from the 3D-LUT 110 and the off data Or, Og, and Ob input from the off data generation circuit 120 according to the setting of the externally given correction prohibit signal F. In response to the correction prohibit signal F set equal to ‘0’, the image signal switchover circuit 130 selectively outputs the standard data Sr, Sg, and Sb input from the 3D-LUT 110. In response to the correction prohibit signal F set equal to ‘1’, on the other hand, the image signal switchover circuit 130 selectively outputs the off data Or, Og, and Ob input from the off data generation circuit 120.

The interpolation operation circuit 140 performs the signal processing described previously, when receiving the selectively output standard data Sr, Sg, and Sb. In the case of selective input of the off data Or, Og, and Ob, the interpolation operation circuit 140 performs the interpolation operation of the input off data Or, Og, and Ob based on the respective lower (k−n) bits of the R, G, and B signals R2, G2, and B2. As mentioned above, the off data Or, Og, and Ob are equivalent to the output of the 3D-LUT 110 on the assumption that the storage of the 3D-LUT 110 is rewritten to have identical input and output. The off data Or, Og, and Ob are subjected to the linear interpolation operation based on the respective lower (k−n) bits of the R, G, and B signals R2, G2, and B2. The R, G, and B signals R3, G3; and B3 output from the interpolation operation circuit 140 are thus identical with the R, G, and B signals R2, G2, and B2 input from the input signal processing circuit 200 into the color correction circuit 100. In this state, the color correction circuit 100 inactivates the color correction function and directly outputs the input R, G, and B signals R2, G2, and B2 as the R, G, and B signals R3, G3, and B3.

C. Functions and Effects

As described above, the color correction circuit 100 of the embodiment readily activates and inactivates the color correction function in response to the setting of the correction prohibit signal F. The interpolation operation circuit 140 requiring the longest time for signal transfer continues activation even in the state of the inactive color correction function. The continued activation of the interpolation operation circuit 140 desirably prevents a deviation of the signal transfer timing in the state of the inactive color correction function from the signal transfer timing in the state of the active color correction function. The arrangement of the color correction circuit 100 thus desirably prevents the disturbance of image display due to the deviated signal transfer timing. The off data generation circuit 120 has the simple circuit structure and avoids the growth of the overall circuit scale of the color correction circuit 100.

There are two possible hardware configurations for inactivating the color correction function of the color correction circuit.

FIG. 4 shows one hardware configuration for inactivating the color correction function of the color correction circuit as a first reference example. In the illustrated reference example of FIG. 4, a color correction circuit A1 receives input R, G, and B signals S1 and performs color correction of the input R, G, and B signals S1. Output R, G, and B signals S2 from the color correction circuit A1 are sent to display devices, such as liquid crystal panels, via an image signal switchover circuit A2. The image signal switchover circuit A2 receives the input signals S1 of the color correction circuit A1, as well as the output signals S2 of the color correction circuit A2. The image signal switchover circuit A2 switches over its output from the output signals S2 to the input signals S1, in response to an externally given correction prohibit signal. This circuit structure enables inactivation of the color correction function of the color correction circuit A1 in response to the externally given correction prohibit signal and causes the image signal switchover circuit A2 to directly output the input signals S1.

The hardware configuration of the first reference example has the relatively small circuit scale but causes a difference in signal transfer timing between one pathway through the color correction circuit A1 (hereafter referred to as ‘first pathway’) and the other pathway with no intervention (hereafter referred to as ‘second pathway’). The difference of the signal transfer timing leads to a problem of horizontal misalignment of the resulting displayed image.

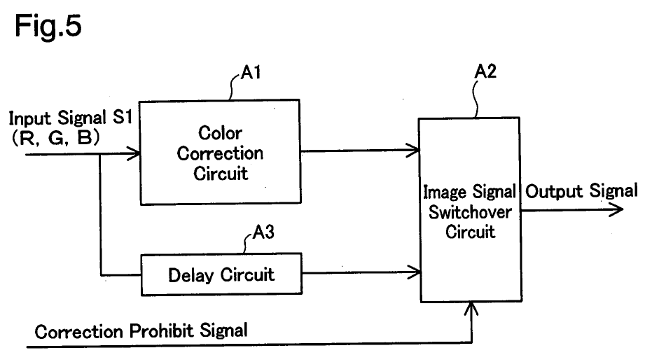

FIG. 5 shows another hardware configuration for inactivating the color correction function of the color correction circuit as a second reference example. The circuit structure of the second reference example additionally has a delay circuit A3 on the second pathway. The delay circuit A3 works to adjust the signal transfer timing on the second pathway to the signal transfer timing on the first pathway. The hardware configuration of this second reference example, however, disadvantageously expands the circuit scale. The delay circuit A3 has a relatively large size, since the color correction circuit A1 has the internal interpolation operation circuit and causes a significant delay of the signal transfer.

The color correction circuit 100 of the embodiment effectively attains the size reduction of the circuit scale and prevents the disturbance of image display due to a deviation of signal transfer timing and is thus advantageous over the hardware configurations of these reference examples.

D. Modifications

(1) Modification 1

In the color correction circuit 100 of the embodiment, the 3D-LUT 110 is constructed as the memory circuit for storage of the standard data Sr, Sg, and Sb having the identical bit widths with those of the R, G, and B signals, as the correction values corresponding to the combination of the respective upper bit portions of the R, G, and B signals. Such storage is, however, neither essential nor restrictive. In one modified structure, a 3D-LUT may store offset values for the respective upper bit portions of the R, G, and B signals, and a downstream adder circuit may add the stored offset values to the upper bit portions of the R, G, and B signals. The 3D-LUT and the adder circuit of the modification constitute the ‘standard data acquisition module’ of the invention. This modified structure desirably reduces the required storage capacity of the 3D-LUT. The ‘standard data acquisition module’ does not essentially require the memory circuit of the 3D-LUT but may alternatively use an operation circuit to compute standard data for correction corresponding to the combination of the respective upper bit portions of the R, G, and B signals.

(2) Modification 2

In the color correction circuit 100 of the embodiment, the off data generation circuit 120 receives the R, G, and B signals R2, G2, and B2 with a value ‘0’, substitutes the respective lower (k−n) bits of the input R, G, and B signals R2, G2, and B2, and outputs the substituted R, G, and B signals as the off data Or, Og, and Ob. The technique of this off data generation circuit 120 is, however, neither essential nor restrictive. Any other suitable technique may be adopted to generate off data having the same k-bit widths as those of the R, G, and B signals R2, G2, and B2, the identical values in their upper n-bit portions with the values in the upper ‘n’ bits of the R, G, and B signals, and the value of ‘0’ in their lower (k−n)-bit portions. Namely the off data generation circuit may have any configuration to give the output equivalent to the output of a 3D-LUT on the assumption that the storage of the 3D-LUT is rewritten to have identical input and output.

(3) Modification 3

In the embodiment described above, each color signal is expressed by three color signals R, G, and B. The R, G, and B signals may be replaced by a luminance signal (Y signal) representing luminance (Y), a first color difference signal (U signal) representing a color difference (U) obtained by subtracting the Y signal from the B signal, and a second color difference signal (V signal) representing a color difference (V) obtained by subtracting the Y signal from the R signal. In this modified arrangement, a YUV conversion circuit is provided upstream of a color correction circuit to convert R, G, and B signals to Y, U, and V signals, and an RGB conversion circuit is provided downstream of the color correction circuit to reconvert the Y, U, and V signals to R, G, and B signals. This modified structure is, however, not restrictive in any sense. For example, when Y, U, and V signals are input as the image signal into the liquid crystal projector, an input signal processing circuit may output Y, U, and V signals as the image signal. This arrangement does not require the YUV conversion circuit provided upstream of the color correction circuit. When R, G, and B liquid crystal panels are designed to allow input of Y, U, and V signals, the RGB conversion circuit provided downstream of the color correction circuit is not required.

(4) Modification 4

The R, G, and B signals R2, G2, and B2, the upper bit portions and the lower bit portions of the R, G, and B signals R2, G2, and B2, and the off data Or, Og, and Ob may have the numbers of bits that are different from those of the above embodiment. These signals, signal bit portions, and off data may have any numbers of bits that satisfy the bit-related conditions described in the embodiment.

(5) Modification 5

The above embodiment regards the liquid crystal projector including the color correction circuit of the first aspects of the invention. The color correction circuit of the first aspects of the invention is, however, not restricted to the liquid crystal projectors but may be applied to diversity of other image display apparatuses.

The color correction circuit, the image display apparatus and the color correction method in accordance with some aspects of the invention have been described above on the basis of the embodiments. The embodiments of the invention are given for easy understanding of the invention and do not limit the invention. It goes without saying that the invention can be modified and improved without deviating from a scope and claims of the invention while the equivalents thereto are included in the invention.

What is claimed is:

1. A color correction circuit that receives three color signals representing a color image as input signals and performs signal processing of the input signals to correct the color of the color image displayed on an image display apparatus,
the color correction circuit comprising:
a standard data acquisition module that divides each of the three input color signals into an upper bit portion and a lower bit portion and acquires standard data for correction corresponding to a combination of the respective upper bit portions of the three color signals;
an interpolation operation module that performs an interpolation operation of the standard data based on the respective lower bit portions of the three color signals to generate color-corrected output signals;
an off data generation module that divides each of the three input color signals into an upper bit portion and a lower bit portion, which have identical bit widths with the bit widths of the upper bit portion and the lower bit portion by the standard data acquisition module, substitutes the respective lower bit portions of the three color signals with a value ‘0’, and outputs three processed color signals after the substitution as off data; and
an interpolation object switchover module that, in response to an externally given correction prohibit instruction for prohibiting color correction, switches over an interpolation object of the interpolation operation module from the standard data to the off data.

2. The color correction circuit of claim 1, wherein the three color signals are a red color signal, a green color signal, and a blue color signal.

3. The color correction circuit of claim 1, wherein the standard data acquisition module has a three-dimensional lookup table that inputs the combination of the respective upper bit portions of the three color input signals as an address signal and outputs the standard data for correction corresponding to the combination of the respective upper bit portions of the three color images.

4. The color correction circuit of claim 3, wherein the three-dimensional lookup table stores the standard data for correction at each of lattice points specified by division of a color space of the three colors into lattices,
the three-dimensional lookup table divides each unit cube defined by preset lattice points in the color space into multiple tetrahedrons and outputs the standard data at respective apexes of each of the multiple tetrahedrons, which include one specific point corresponding to a combination of tone values of the upper bit portions, and
the interpolation operation module performs linear interpolation of the standard data for correction output from the three-dimensional lookup table to generate color-corrected data corresponding to tone values of the lower bit portions.

5. The color correction circuit of claim 1, wherein the interpolation object switchover module includes a signal switchover circuit that receives both an output signal of the standard data acquisition module and an output signal of the off data generation module, and outputs the output signal of the off data generation module to the interpolation operation module in response to external input of the correction prohibit instruction, while outputting the output signal of the standard data generation module to the interpolation operation module in response to no external input of the correction prohibit instruction.

6. An image display apparatus including the color correction circuit in accordance with claim 1.

7. A color correction method of receiving three color signals that represent a color image as input signals and performing signal processing of the input signals to correct the color of the color image displayed on an image display apparatus,
the color correction method comprising:
dividing each of the three input color signals into an upper bit portion and a lower bit portion and acquiring standard data for correction corresponding to a combination of the respective upper bit portions of the three color signals;
performing an interpolation operation of the standard data based on the respective lower bit portions of the three color signals to generate color-corrected output signals;
dividing each of the three input color signals into an upper bit portion and a lower bit portion, which have identical bit widths with the bit widths of the divided upper bit portion and lower bit portion, substituting the respective lower bit portions of the three color signals with a value ‘0’, and outputting three processed color signals after the substitution as off data; and
in response to an externally given correction prohibit instruction for prohibiting color correction, switching over an interpolation object of the interpolation operation from the standard data to the off data.
